(19) United States
(12) Patent Application Publication
(10) Pub. No.: US 2018/0220559 A1
(43) Pub. Date: Aug. 2, 2018

(54) Transparent Electromagnetic Shielding using Hybrid Graphene/Metal Nanomesh Structures

(71) Applicant: SPAWAR Systems Center Pacific, San Diego, CA (US)

(72) Inventors: Mitchell B. Lerner, San Diego, CA (US); John D. Rockway, San Diego, CA (US)

(73) Assignee: United States of America as represented by Secretary of the Navy, San Diego, CA (US)

(21) Appl. No.: 15/422,537

(22) Filed: Feb. 2, 2017

(51) Int. Cl. H05K 9/00; B32B 5/02; B32B 15/02

(52) U.S. Cl. CPC H05K 9/0088; H05K 9/009; B32B 2307/412; B32B 15/02; B32B 5/028

(57) ABSTRACT

A transparent electromagnetic shield is fabricated by combining a metal nanomesh structure and a graphene sheet. The nanomesh structure is formed such that spacing between portions of the nanomesh provides optical transparency and also provides electromagnetic shielding. The graphene sheet is placed over the nanomesh structure and adhered to the nanomesh structure. The graphene sheet provides additional electromagnetic shielding and maintains the optical transparency.

### FEDERALLY-SPONSORED RESEARCH AND DEVELOPMENT

The United States Government has ownership rights in this invention. Licensing inquiries may be directed to Office of Research and Technical Applications, Space and Naval Warfare Systems Center, Pacific, Code 72120, San Diego, Calif., 92152; telephone (619) 553-5118; email: ssc pac t2@navy.mil, referencing NC 102744.

### FIELD OF THE INVENTION

The present invention pertains generally to electromagnetic shielding. More particularly, the present invention pertains to electromagnetic shielding using a hybrid metal nanomesh/graphene structure.

### BACKGROUND OF THE INVENTION

Persistent exposure to electromagnetic (EM) radiation is not only harmful to humans, it can also disrupt the functioning of electronic instruments in, for example, an airplane. Further, it may be tactically undesirable to have EM radiation leaking out of, for example, an airplane that allows others to deduce the location of the airplane.

EM shielding reduces the transmission of an electromagnetic field by blocking it with a conductor or magnetic material. The amount of shielding depends strongly on the type of material used, its size, shape and orientation with respect to the incoming radiation.

Transparent EM shielding is necessary for any application in which humans need to maintain visibility while being electrically isolated, such as in an airplane cockpit.

Several materials have been used as EM shields, including metallic meshes, metal powders in a glass matrix, and conducting oxides. However, these materials each have significant drawbacks. Metallic meshes are often heavy and expensive. Metal powders are typically expensive. For example, gold is desirable to use for shielding due it to its chemical inertness, yet gold is prohibitively expensive for most applications. Other particles can oxidize and degrade in performance. Conductive oxides, such as indium-tin oxide (ITO) and fluorine-doped tin oxide (FTO), are brittle and moderately resistive, making them poor shielding materials.

In view of the above, there is a need for a hybrid transparent electromagnetic shield that exhibits effective electromagnetic shielding, yet is optically transparent.

### SUMMARY OF THE INVENTION

According to an illustrative embodiment, a method is provided for fabricating a transparent electromagnetic shield. The method includes forming a metal nanomesh structure on a surface and placing a graphene sheet over the nanomesh structure. The graphene sheet is caused to adhere to the nanomesh structure, resulting in a hybrid metal nanomesh/graphene shield that effectively shields against electromagnetic radiation yet is at least adequately optically transparent.

These, as well as other objects, features and benefits will now become clear from a review of the following detailed description, the illustrative embodiments, and the accompanying drawings.

### BRIEF DESCRIPTION OF THE DRAWINGS

The novel features of the present invention will be best understood from the accompanying drawings, taken in conjunction with the accompanying description, in which similarly-referenced characters refer to similarly-referenced parts, and in which:

FIG. 1 illustrates a stage in a process for fabricating a hybrid mesh/graphene transparent electromagnetic magnetic shield.

FIG. 2 illustrates a second stage in a process for fabricating a hybrid mesh/graphene transparent electromagnetic shield.

FIG. 3 illustrates a third stage in a process for fabricating a hybrid mesh/graphene transparent electromagnetic shield.

FIG. 4 illustrates the final stage in a process for fabricating a hybrid mesh/graphene transparent electromagnetic shield.

FIG. 5 is a flow chart illustrating the steps involved in process for fabricating a hybrid metal nanomesh-graphene transparent electromagnetic shield according to several embodiments.

### DETAILED DESCRIPTION OF THE EMBODIMENTS

According to illustrative aspects, a transparent electromagnetic shield is provided that is a hybrid device including a metallic nanomesh and a graphene sheet.

The metal nanomesh has a low resistance and is a very effective electromagnetic shield. The metal nanomesh also can be configured to provide at least an adequate amount of transparency. The graphene is optically transparent and allows visible light to pass through. Graphene also has high carrier mobility, resulting in low sheet resistance. Integrating the metal nanomesh with the graphene results in a hybrid structure that may be expected to perform better than either the nanomesh material or the graphene material, alone.

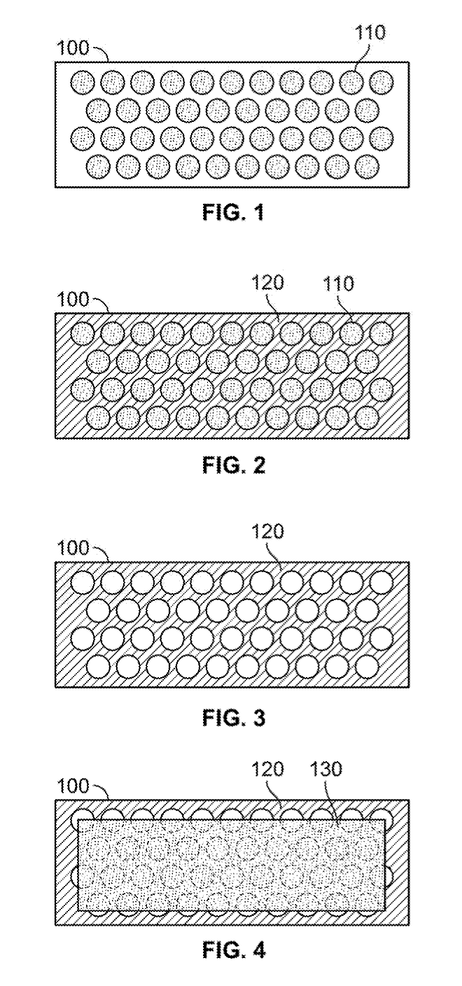

Referring now to the drawings, FIGS. 1-4 illustrate states in a process for fabricating a hybrid mesh/graphene transparent electromagnetic shield according to an illustrative embodiment. In the embodiment shown in and discussed with respect to FIG. 1, a copper mesh may be fabricated by nanosphere lithography. It should be appreciated that other methodologies may be used to fabricate the copper mesh, such as e-beam lithography or photolithography. Nanosphere lithography is described here for ease of description and illustration. Further, it should be appreciated that other metals may be used for the nanomesh, and copper is described herein only be way of example.

As shown in FIG. 1, polystyrene (PS) microspheres 110 are assembled on, e.g., a glass surface 100. In preparation for assembly on the glass surface 100, the PS microspheres 110 may be put into an ethanol and water mixture. In this solution, the PS microspheres 110 self-assemble into hexagonal domains at the ethanol/water interface, due to different surface tensions. The hexagonally arranged spheres 110 may be transferred onto the glass surface 100, without disturbing their order. The PS spheres 110 may then be etched in oxygen plasma to control the relative spacing between the PS spheres. Lower etching times result in larger inter-sphere spacing with less area covered by the microspheres 110.

FIG. 2 shows the next stage in a process for fabricating a hybrid mesh/graphene transparent electromagnetic shield in which a layer of copper (or other metal) 120 is deposited over the PS microspheres 110 on the glass surface 100. The microspheres 110 act as a protective layer so that copper 120 is only deposited on the glass surface 100 in between the microspheres 110, forming a nanomesh structure. Spacing between portions of the copper nanomesh may be controlled such that a desired amount of electromagnetic shielding is provided and an adequate amount of transparency is achieved. The spacing may be controlled by adjusting the etching times of the PS microspheres 110.

FIG. 3 shows the next stage in a process for fabricating a hybrid mesh/graphene transparent electromagnetic shield in which the PS microspheres 110 are removed, e.g., by sonicating in toluene. This leaves only the patterned copper nanomesh 120 on the glass surface 100.

FIG. 4 shows the final stage in a process for fabricating a hybrid mesh/graphene transparent electromagnetic shield in which a sheet of graphene 130 is placed on the copper nanomesh 120. The graphene may be supported by a polymethyl methacrylate (PMMA) layer and may be grown as described in more detail below. A hot plate bake may be used to promote adhesion between the graphene 130 and the nanomesh 120. The resulting electromagnetic shield, including the copper nanomesh and the graphene sheet 130, is shown in FIG. 4.

Although not illustrated or described in detail, it should be appreciated that the graphene sheet may be grown by any suitable method, e.g., chemical vapor deposition on copper foil, mechanical exfoliation, epitaxial growth, or chemical synthesis.

For ease of explanation, growth of a graphene sheet by chemical vapor deposition on copper foil is described herein. The graphene is grown at high temperatures, e.g., approximately 1050 degrees Celsius. The graphene may be coated with a PMMA layer to provide support.

The graphene can be removed from the copper foil by bubble transfer or chemical etching. In the case of bubble transfer, the graphene layer, supported by a PMMA layer, is electrochemically separated from the copper by applying a voltage between the copper sheet and a bath containing NaOH. Bubbles form at the electrodes, lifting off the graphene/PMMA stack. Similarly, the PMMA/graphene/copper could be placed in an etchant, such as iron chloride or ammonium persulfate to etch away the copper, thus leaving the PMMA/graphene layers. When the PMMA/graphene is separated from the copper foil, the graphene/PMMA stack can be transferred to the copper nanomesh, as shown in FIG. 4.

Once the graphene is adhered to the metal nanomesh, fabrication is complete. A number of fabricated hybrid metal nanomesh-graphene shields, such as that shown in FIG. 4, may be applied to any surface which requires maintained visibility and electrical isolation, e.g., a windshield in an airplane cockpit or a window in a ship control room. Those skilled in the art will appreciate that the fabricated shield may be applied in any conventional way, e.g., using adhesive to attach the metal nanomesh side to a windshield, window, etc.

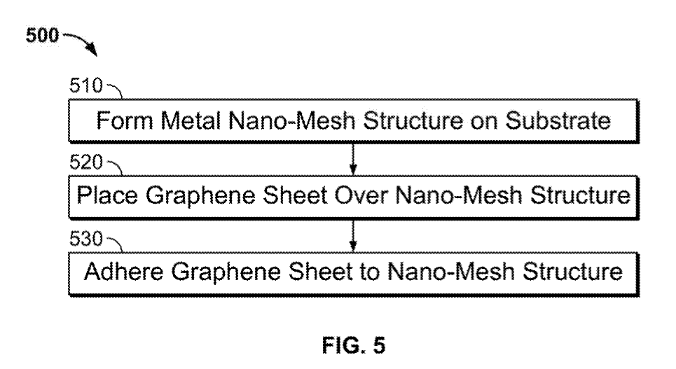

FIG. 5 is a flow chart illustrating the steps involved in process 500 for fabricating a hybrid metal nanomesh-graphene transparent electromagnetic shield according to illustrative embodiments. It should be appreciated that the steps and order of steps described and illustrated are provided as examples. Fewer, additional, or alternative steps may also be involve in the fabrication of the shield, and/or some steps may occur in a different order.

Referring to FIG. 5, the process for fabricating a hybrid mesh-graphene transparent electromagnetic shield begins at step 510 at which a metal nanomesh structure is formed on a substrate, such as glass. At step 520, a graphene sheet is placed on the nanomesh structure, thereby increasing the electromagnetic shielding while maintaining transparency. The metal nanomesh may be formed using any of the techniques described above. The spacing between the portions of nanomesh structure may be selected to provide a desired or at least an adequate amount of electromagnetic shielding, considered in conjunction with the electromagnetic shielding provided by the graphene sheet, and to provide a desired or at least an adequate amount of transparency which is maintained by the graphene sheet. At step 530, the graphene sheet is adhered to nanomesh structure using, e.g., a hot bake.

The hybrid metal nanomesh/graphene structure described above is a tradeoff between optimal electromagnetic shielding and transparency. The metal nanomesh repels an electromagnetic field as the field contacts the nanomesh. The graphene also acts to provide electromagnetic shielding. While the nanomesh provides some transparency, visible light is impeded from passing through the mesh structure. By making the spacing in the mesh structure wider but maintaining enough mesh for electromagnetic shielding, more light is allowed to come through. The spacing between the portions of the metal mesh may be selected so that the transparency is at least adequate. Combining the graphene sheet with the metal mesh ensures that adequate electromagnetic shielding is provided yet also maintains the transparency, allowing a high percentage of the visible light to pass through.

Such a design is expected to provide, for example, optical transparency that greater than 85%, low sheet resistance (less than 5 ohms/square and high carrier mobility (greater than 1000 centimeters squared per Volt-second (cm²/V*s) for graphene). There are no known materials that could match the performance of this hybrid structure. As such, the shielding according to illustrative embodiments provide conformable, transparent shielding which is capable of blocking electromagnetic radiation from the Megahertz to Gigahertz frequency range.

The use of the terms “a” and “an” and “the” and similar references in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Various embodiments of this invention are described herein. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method for fabricating a transparent electromagnetic shield, comprising:
forming a metal nanomesh structure on a surface;
placing a graphene sheet over the nanomesh structure; and
causing the graphene sheet to adhere to the nanomesh structure, thereby forming the transparent electromagnetic shield.

2. The method of claim 1, wherein the metal nanomesh structure is formed by a nanosphere lithography process.

3. The method of claim 2, wherein the nanosphere lithography process includes depositing a layer of metal over polystyrene microspheres assembled on the surface and removing the polystyrene microspheres from the surface.

4. The method of claim 3, further comprising etching the assembled polystyrene microspheres, such that there are desired spaces between the microspheres assembled on the surface, and the metal is deposited only onto the desired spaces between the microspheres assembled on the surface.

5. The method of claim 1, wherein the metal nanomesh structure is formed using at least one of e-beam lithography and photolithography.

6. The method of claim 1, wherein the graphene sheet is grown by chemical vapor deposition on copper foil.

7. The method of claim 6, wherein the graphene sheet is removed from the copper foil by at least one of chemical etching and bubble transfer.

8. The method of claim 1, wherein the graphene sheet is grown by at least one of mechanical exfoliation, epitaxial growth and chemical synthesis.

9. The method of claim 1, further comprising shaping the transparent electromagnetic shield by at least one of photolithography, e-beam lithography, and shadow-masking to provide a desired dimension for a particular shielding application.

10. A transparent electromagnetic shield, comprising:
a metal nanomesh structure providing electronic magnetic shielding, wherein the metal nanomesh structure provides optical transparency; and
an optically transparent graphene sheet applied to the metal nanomesh structure, wherein the graphene sheet provides additional electromagnetic shielding while maintaining the optical transparency for the transparent electromagnetic shield.

11. The transparent electromagnetic shield of claim 10, wherein the metal nanomesh structure is formed by at least one of nanosphere lithography, e-beam lithography, and photolithography.

12. The transparent electromagnetic shield of claim 10, wherein the graphene sheet is grown by at least one of chemical vapor deposition, mechanical exfoliation, epitaxial growth and chemical synthesis.

13. The transparent electromagnetic shield 10, wherein the transparent electromagnetic shield is shaped by at least one of photolithography, e-beam lithography, and shadow-masking to provide a desired dimension for a particular shielding application.

14. The transparent electromagnetic shield of claim 10, wherein the graphene sheet is supported by a polymethyl methacrylate layer.

15. The transparent electromagnetic shield of claim 10, wherein the metal nanomesh is made of copper.

16. A method for fabricating a transparent electromagnetic shield, comprising:
forming a metal nanomesh structure on a surface, wherein the nanomesh structure is formed such that there is a desired spacing between portions of the nanomesh structure to provide optical transparency, wherein the metal nanomesh structure also provides electromagnetic shielding; and
adhering an optically transparent graphene sheet to the nanomesh structure, wherein the graphene sheet provides additional electromagnetic shielding and maintains the optical transparency.

17. The method of claim 16, wherein the desired spacing between portions of the nanomesh structure is selected so that the metal nanomesh structure provides a desired amount of electromagnetic shielding, considered in conjunction with the electromagnetic shielding provided by the graphene sheet.

18. The method of claim 17, wherein the desired spacing between portions of the nanomesh structure is further selected so that the metal nanomesh structure provides transparency which is maintained by the optically transparent graphene sheet.

19. The method of claim 16, further comprising shaping the transparent electromagnetic shield to provide a desired dimension for a particular shielding application.

20. The method of claim 19, wherein said shaping is performed using at least one of photolithography, e-beam lithography, and shadow-masking.
